(19) United States
(12) Patent Application Publication
(10) Pub. No.: US 2016/0064768 A1
(43) Pub. Date: Mar. 3, 2016

(54) SUBSTRATE FOR THIN FILM MICROBATTERIES

(71) Applicants: Kobi Goldstein, Lapid (IL); Larisa Askadsky, Bat Yam (IL); Larisa Postel, Ashdod (IL)

(72) Inventors: Kobi Goldstein, Lapid (IL); Larisa Askadsky, Bat Yam (IL); Larisa Postel, Ashdod (IL)

(21) Appl. No.: 14/472,526

(22) Filed: Aug. 29, 2014

(51) Int. Cl. H01M 10/04; G03F 7/20; G03F 7/16

(52) U.S. Cl. CPC H01M 10/04; G03F 7/16; G03F 7/20

(57) ABSTRACT

A method for fabricating electrical storage cell including providing a photopolymer; providing a pre-patterned mask wherein the pre-patterned mask includes masked regions and unmasked regions; attaching the pre-patterned mask on top of the photopolymer; applying collimated ultraviolet radiation on the masked substrate wherein areas of the photopolymer underneath of the unmasked regions are solidified or cross linked and areas of the photopolymer underneath the masked are not solidified or cross linked to form an imaged substrate with perforated holes; developing the imaged substrate; cleaning residual material from the perforated holes; forming a thin film over the surface of a substrate area to define an anode, a cathode; and forming a solid electrolyte disposed between the anode and the cathode, wherein the thin film comprising a final layer which is formed so as to fill the perforated holes.

### CROSS REFERENCE TO RELATED APPLICATIONS

Reference is made to commonly-assigned copending U.S. patent application Ser. No. ______(Attorney Docket No. K001863US01NAB), filed herewith, entitled SYSTEM FOR FABRICATING AN ELECTRICAL STORAGE CELL, by Goldstein; the disclosure of which is incorporated herein.

### FIELD OF THE INVENTION

The present invention relates generally to the field of electrical energy sources and specifically to a substrate for thin film microbatteries.

### BACKGROUND OF THE INVENTION

U.S. Pat. No. 7,527,897 (Nathan et al.) presents a three-dimensional storage cell, such as a microbattery. The storage cell is produced by forming multiple thin film layers on a microchannel plate (MCP) structure. The thin film layers cover the inner surfaces of the microchannel tubes. Typically, the thin film layers also cover the upper and/or lower surfaces of the plate in order to provide electrical continuity of the layers over the entire MCP. The layers inside the tubes completely fill the volume of the tube. The MCP may be made from glass or from other suitable materials, as described above, and the thin film layers may be deposited using a variety of liquid or gas-phase processes.

Although MCPs themselves are well known in the art of radiation and electron detection, their use as a substrate for energy-storage devices is novel. Because of the processes by which MCPs are made by fusing together multiple tubes they can be made with very small channel diameters, high channel density and high channel aspect ratio. As a result, MCP-based microbatteries have a larger electrode area/volume ratio, and thus higher electrical capacity, than microbatteries known in the art, such as those described in the above-mentioned U.S. Pat. No. 6,197,450 (Nathan et al.). The term “microbattery” as used herein simply denotes small-scale electrical batteries, in which certain features of the present invention are particularly advantageous, but the principles of the present invention are generally applicable to batteries and other electrical storage cells regardless of scale.

The energy storage device will typically include a micro channel plate (MCP) having channels formed therein, the channels having surface areas; and thin films formed over the surface areas and defining an anode, a cathode, and a solid electrolyte disposed between the anode and the cathode.

Typically, the MCP includes a plurality of tubes, which are fused together and cut to define the MCP, the tubes having lumens, which define the channels. The tubes may include glass or carbon. The MCP may include a non-conductive material or a conductive material. The MCP has top and bottom surfaces, and the thin films are further formed over at least one of the top and bottom surfaces.

The current invention discloses a method and an article of a substrate with perforated channels adapted for microbatteries based MCP.

### SUMMARY OF THE INVENTION

Briefly, according to one aspect of the present invention a method for fabricating electrical storage cell including providing a photopolymer; providing a pre-patterned mask wherein the pre-patterned mask includes masked regions and unmasked regions; attaching the pre-patterned mask on top of the photopolymer; applying collimated ultraviolet radiation on the masked substrate wherein areas of the photopolymer underneath the unmasked regions are solidified or cross linked and areas of the photopolymer underneath the masked are not solidified or cross linked to form an imaged substrate; developing the imaged substrate; cleaning residual material from the areas which are not solidified to form perforated holes; forming a thin film over the surface of a substrate area to define an anode; and forming a solid electrolyte over the anode and the cathode, wherein the thin film comprising a final layer which is formed so as to fill the perforated holes.

The invention and its objects and advantages will become more apparent in the detailed description of the preferred embodiment presented below.

### BRIEF DESCRIPTION OF THE DRAWINGS

FIG. 1 represents in diagrammatic form of a digital front end driving an imaging device (prior art);

FIG. 2 represents in diagrammatic form a laser imaging head mounted on an imaging carriage which images on a plate mounted on an imaging cylinder (prior art);

FIG. 3 represents in diagrammatic form a honeycomb shape used to form an image on a film mask;

FIG. 4 represents in diagrammatic form a film mask with a honeycomb shape image which will be attached to a photopolymer plate;

FIG. 5 represents in diagrammatic form a substrate built from a pre-patterned mask attached to a photopolymer plate;

FIG. 6 depicts a top view matrix of perforated holes made by collimated UV exposure of a substrate;

FIG. 7A shows a top view of perforated holes made by collimated UV exposure of a substrate;

FIG. 7B shows a close up view of perforated holes made by collimated UV exposure of the substrate shown in FIG. 7A;

FIG. 8 shows a side view of the perforated holes made by collimated UV exposure of the substrate shown in FIGS. 7A and 7B, showing the depth of the perforated holes;

FIG. 9 shows a photopolymer plate after imaging and development, being treated by water jets to remove debris from non solidified regions;

FIG. 10 shows micro battery structure showing several perforated holes filled with battery material (current collector, cathode and electrolyte layers);

FIG. 11 shows an anode layer added to structure of FIG. 10;

FIG. 12 shows a second current collector added to structure of FIG. 11; and

FIG. 13 shows a cutaway view of honeycomb structure cells with deposited micro battery materials.

### DETAILED DESCRIPTION OF THE INVENTION

In the following detailed description, specific details are set forth in order to provide a thorough understanding of the disclosure. It will be understood, however, by those skilled in the art that the teachings of the present disclosure may be practiced without these specific details. In other instances, well-known methods, procedures, components and circuits have not been described in detail so as not to obscure the teachings of the present disclosure.

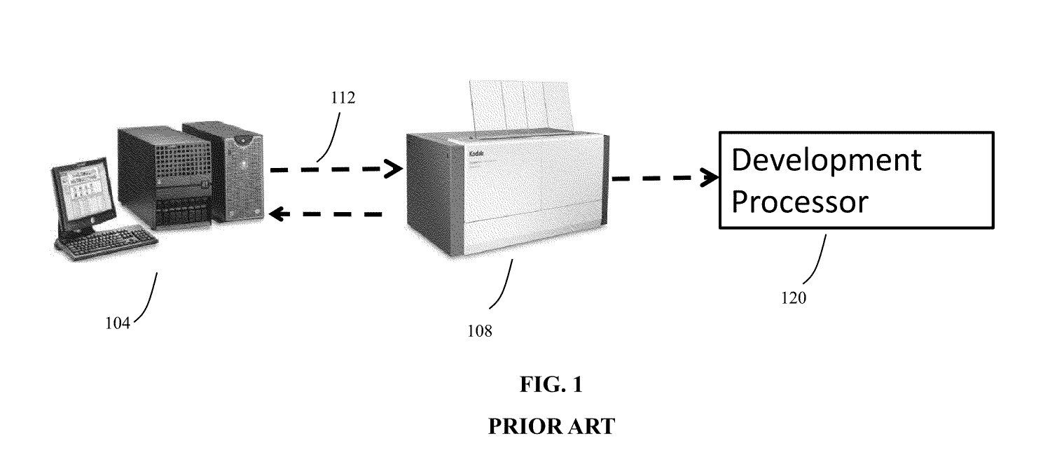

FIG. 1 shows a an imaging device 108. The imaging device is driven by a digital front end (DFE) 104. The DFE receives printing jobs in a digital form from desktop publishing (DTP) systems (not shown), and renders the digital information for imaging. The rendered information and imaging device control data are communicated between DFE 104 and imaging device 108 over interface line 112.

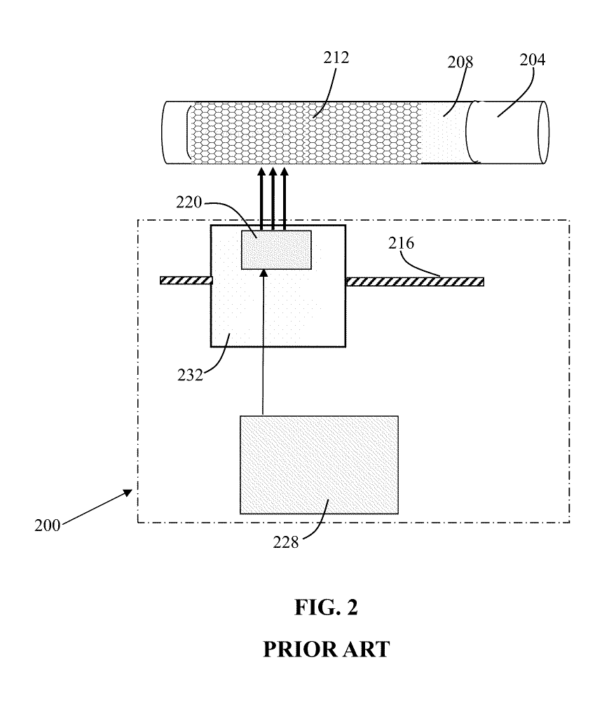

FIG. 2 shows an imaging system 200. The imaging system 200 includes an imaging carriage 232 an imaging head 220. Imaging head 220 are controlled by controller 228. The imaging head 220 is configured to image on a film substrate 208. The substrate may be a film to be attached as a mask to a flexographic plate, or alternatively a flexographic plate that will be directly imaged by imaging system 200. FIG. 2 shows a substrate 208 mounted on a rotating cylinder 204 for exposure, the imaging device can be based on a flat bed imaging head as well. The carriage 232 is adapted to move substantially parallel to cylinder 204 guided by an advancement screw 216. The substrate 208 is imaged by imaging head 220 to form imaged data 212 on substrate 208.

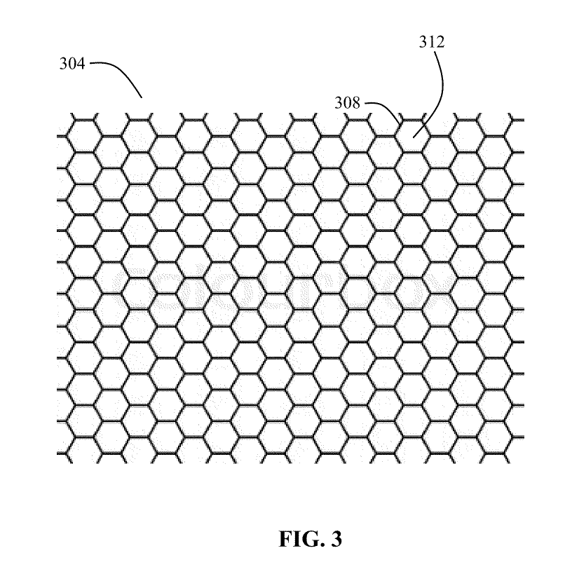

FIG. 3 shows a honeycomb image 212. The rendered image 212 was prepared by DFE 104, to be further imaged on film mask 208.

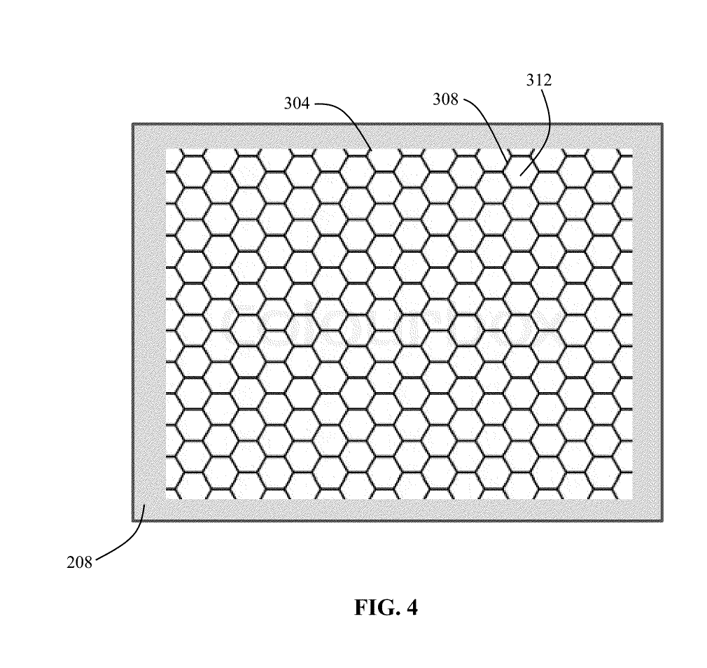

FIG. 4 shows an exposed film mask 208 with honeycomb image shape 304. The exposed film mask 208 is pre-patterned where the boundaries or the walls 308 represent the non masked areas and the holes 312 represent the masked area when UV radiation will be applied.

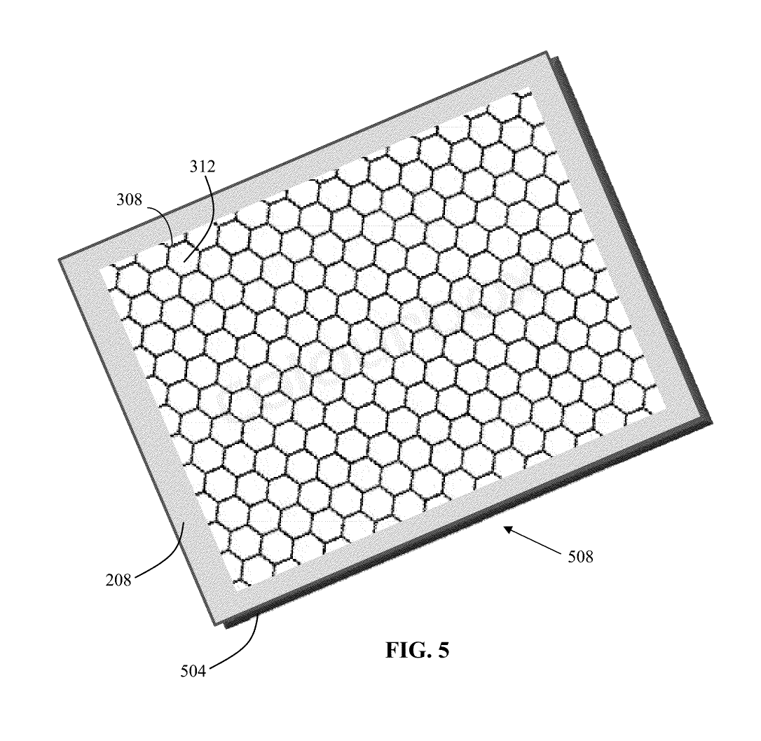

Mask 208 is attached on top of the photopolymer plate 504 to form substrate 508 as is shown in FIG. 5. Plate 504 is made of a photo sensitive layer comprising a binder, a monomer and a photo initiator. The binder is usually made from a thermoplastic elastomeric block copolymer such as an SBS (styrene butadiene styrene), natural rubber or a styrene-isoprene. The monomer is usually a poly functional acrylate such as isobornyl acrylate, 2-phenoxyethyl acrylate or hexane diol diacrylate. The photo initiator is an ultra violet (UV) light triggered to start the photopolymer reaction. The photo initiator is usually a benzophenone, benzoin which is known by commercial name such as Irgacure 651.

Collimated ultra violet (UV) radiation is applied on substrate 508 to solidify or crosslink areas under the unmasked areas 308, and not change the properties of the masked areas 312, thereby to produce straight perforated holes under the masked areas 312 of substrate 508 (the UV emission process is not shown). The collimated emission can be applied by UV light.

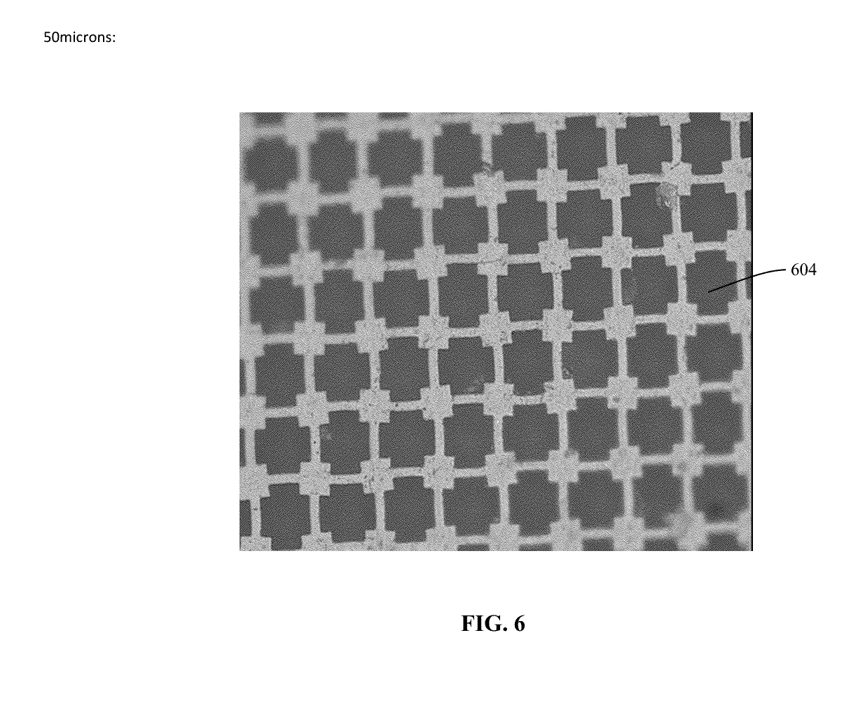

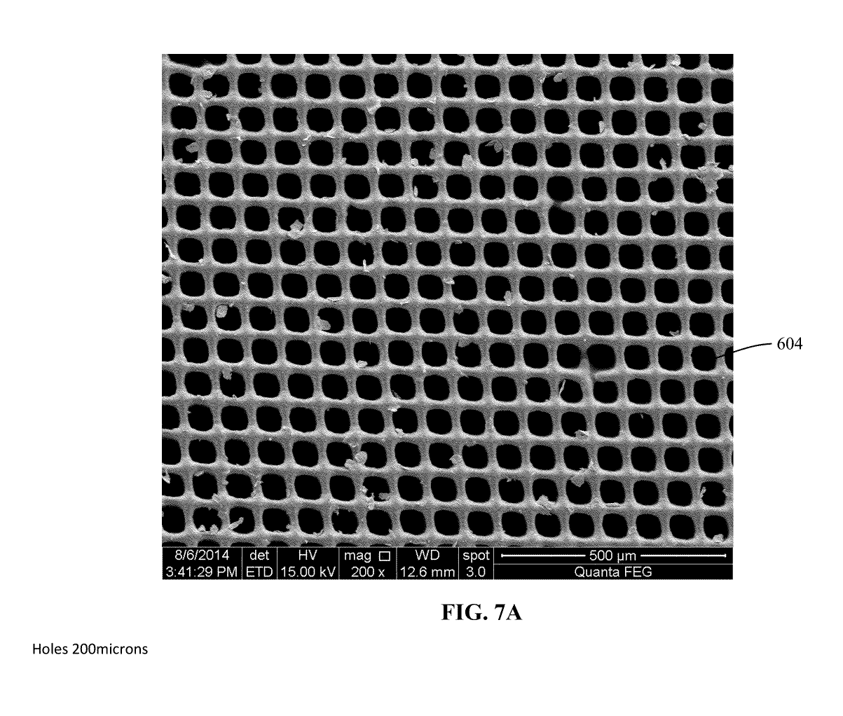

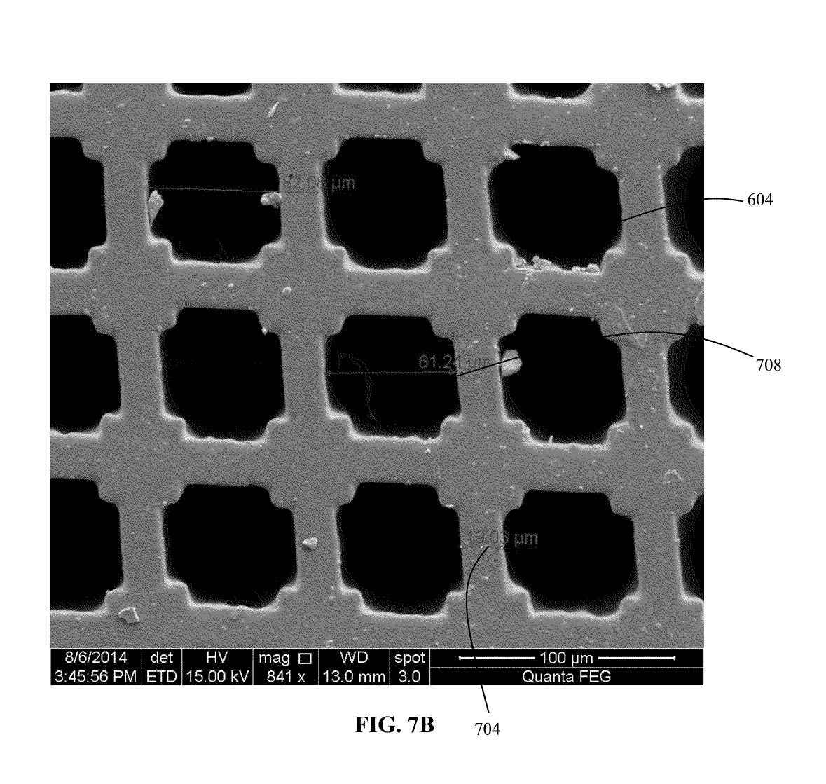

FIG. 6 and FIG. 7A show a top view of the perforated holes 604 produced by the collimated UV light source after removal of the residual material. UV light sources are described at http://www.oainet.com/oai-lightsrcGrande-pp.html. The holes 604 are formed under masked areas 204, shown in FIG. 5.

FIG. 7B shows a close up view of the perforated holes 604. The perforated holes have an approximated holes diameter 708 of 60 micrometers and distance between holes 704 of 20 micrometers.

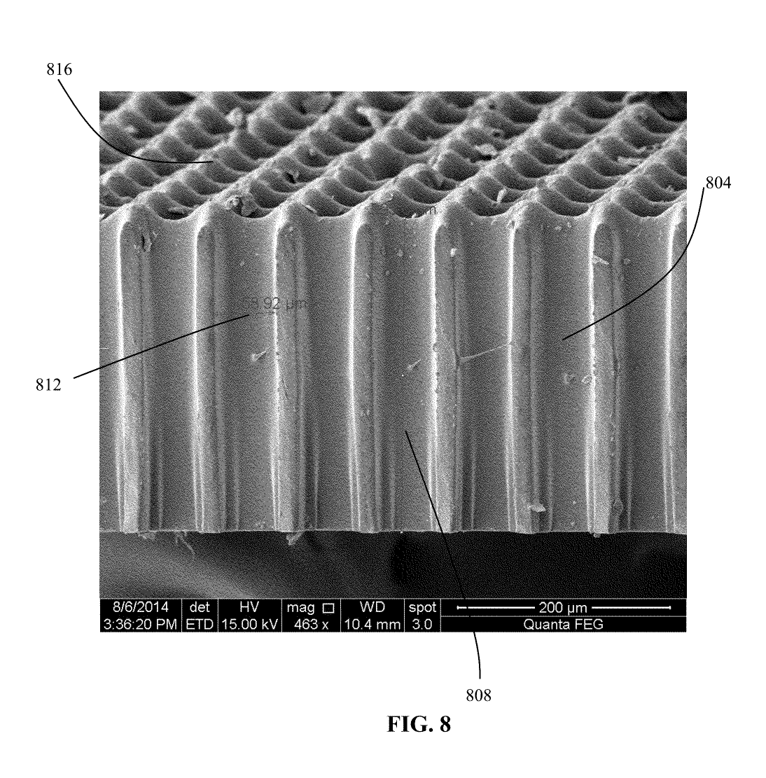

FIG. 8 shows a side view of the perforated holes depth structure 804. The shown perforated holes depict a pattern of 60 by 20 micrometer pattern. The diameter 812 is 60 micrometer in size whereas the distance between holes are shown to be around 20 micrometer, the depth of the holes 808 shown to be around 300 micrometers. The shown pattern 804 was achieved by 5 minutes exposure followed by 10 minutes development at room temperature.

Following the applied collimated UV radiation the exposed parts are cross linked and the masked parts are removed by solvent using a development processor 120 (shown in FIG. 1). The solvents that can be used are aromatic or aliphatic hydrocarbons such as diisopropyl benzene.

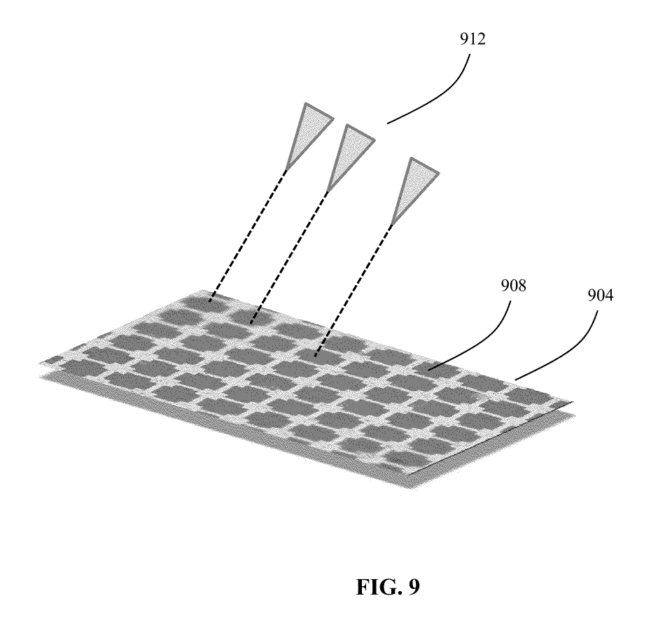

Referencing FIG. 9, non-solidified material 908 on imaged and developed plates 904 is cleaned to form straight holes in the substrate. The cleaning process may utilize means such as water jets, brushes or by ultra sonic means. FIG. 9 shows water jets 912 applied on plate 904 to remove the non-solidified areas 908 to form perforated holes 816 as is shown in FIG. 8.

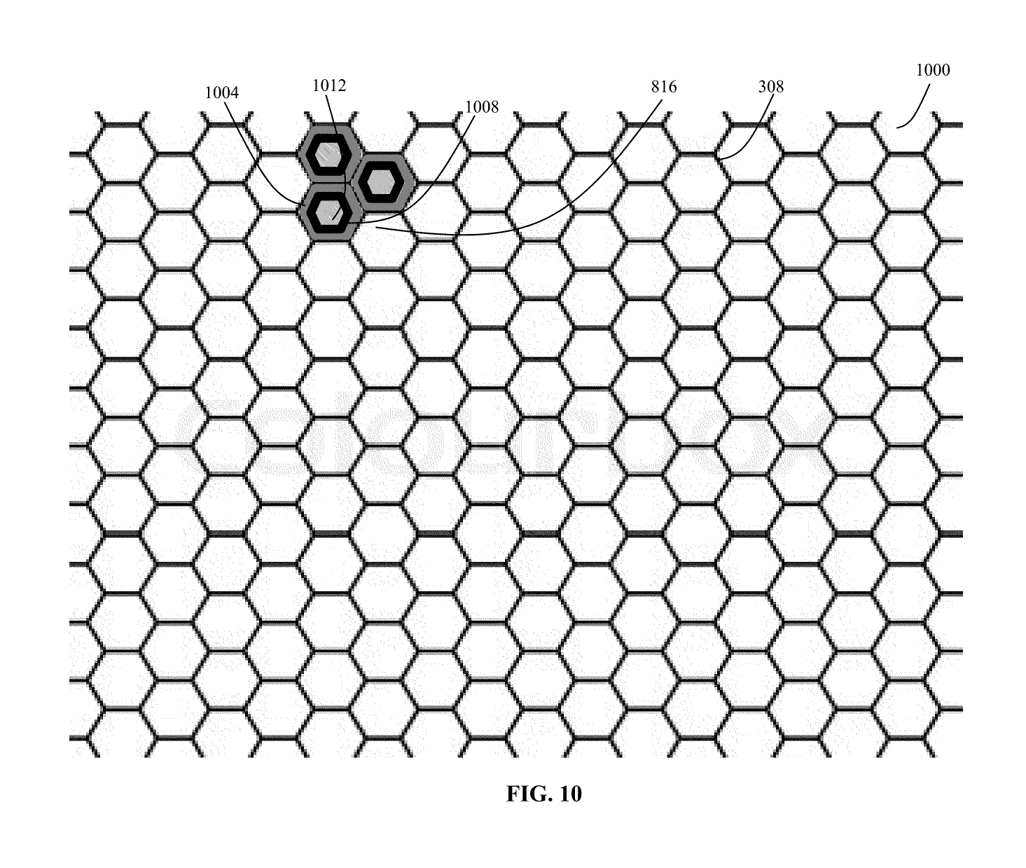

FIG. 10 shows several perforated holes 816 filled with microbattery material which forms first current collector layer 1004 the perforated holes. Layer 1004 typically comprises a metallic layer, which is deposited over substrate 1000 using any suitable thin-film deposition process known in the art (not shown). Typically, collector 1004 forms a hollow structure or crust that coats the entire surface area of the perforated substrate.

A cathode layer 1008 is formed over the first current collector layer 1004. The cathode layer 1008 may be formed using an electrochemical deposition process or using any other suitable method, such as electroless deposition and chemical vapor deposition.

An electrolyte separator layer 1012 is applied over cathode layer 1008 to form the separator layer of the microbattery, as is known in the art. In some embodiments, the electrolyte separator layer comprises an ion-conducting electrolyte membrane 1012.

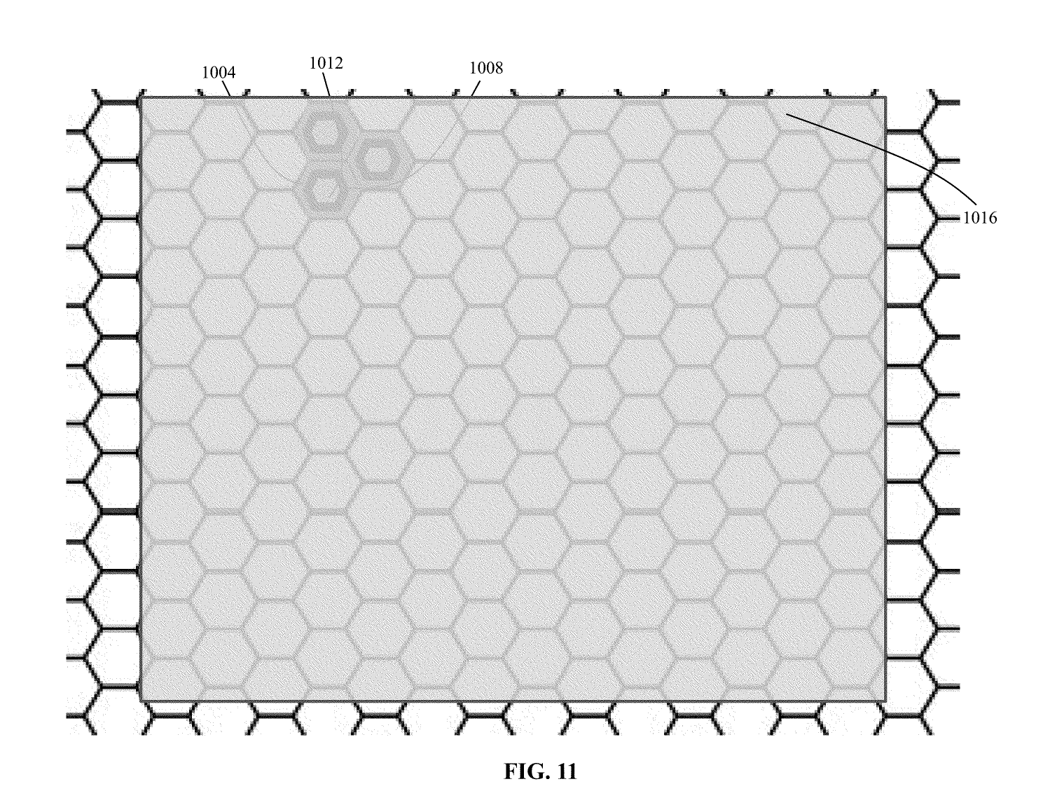

An anode layer 1016 as is shown in FIG. 11 is formed on or otherwise attached to the outer surface or surfaces of electrolyte separator 1012. The anode layer 1016 comprises a substantially flat layer or film of conductive material. The anode may be deposited onto the outer surface of the membrane using a thin- or thick-film deposition process. Alternatively, the anode may comprise a thin foil made of anode material and attached to the surface of the membrane. The anode layer may either be attached to one or both outer surfaces of electrolyte separator 1012.

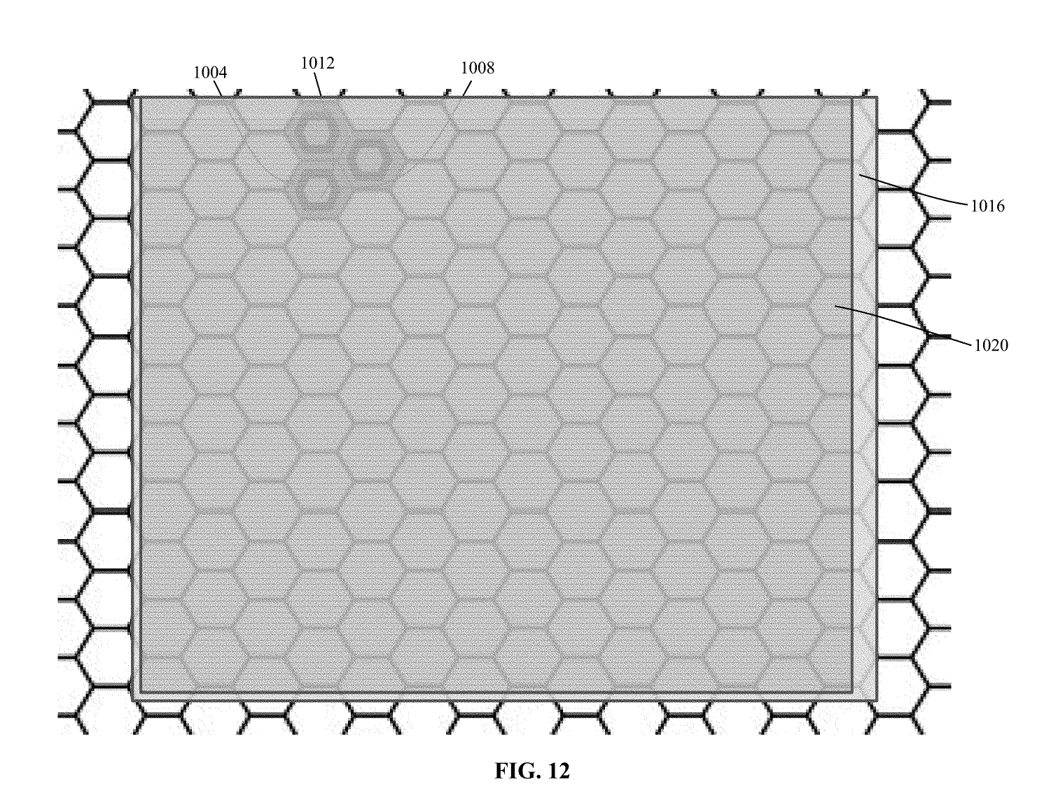

A second current collector layer 1020 of conductive material as is shown in FIG. 12 is optionally attached to the anode layer 1016.

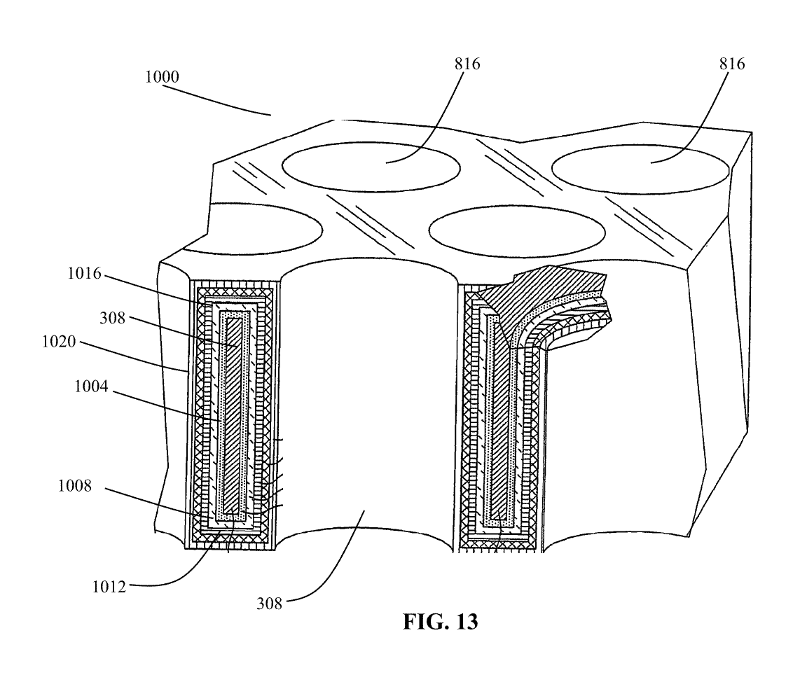

FIG. 13 is a schematic, cutaway view of micro battery substrate 1000 showing details of thin film structure in the interior of perforated holes 816, in accordance with an embodiment of the present invention. The relative thickness of the thin film layers is exaggerated in the figure for clarity of illustration. It can be seen in the figure that the layers both cover the interior walls 308 of perforated holes 816 and extend over the upper or lower surfaces or both of the substrate 1000. The thin film layers may be deposited using any suitable processes known in the art, such as wet processes or chemical vapor deposition (CVD) processes. Some specific fabrication examples are described herein below.

In the embodiment shown in FIG. 13, a current collector layer 1004 is deposited over the substrate and thus coats wall 308. An cathode layer 1008, which may be either the anode or the cathode of perforated substrate 1000, is deposited over current collector layer 1004. Alternatively, the current collector layer may be eliminated if cathode layer 1008 is capable of serving the current collection function, or if wall 308 is itself made of conductive material, such as a suitable form of carbon. In an alternative embodiment, the battery substrate also serves as one of the electrodes, such as the anode. In this case, both cathode layer 1008 and anode layer 1016 may be eliminated from structure.

Cathode layer 1008 is overlaid by an electrolyte layer 1012, typically a solid electrolyte in a polymer matrix. A second (cathode or anode) electrode layer 1016 is formed over electrolyte layer 1012. If necessary, electrode layer 1016 is followed by another (optional) current collector layer 1020. Alternatively, if electrode layer 1016 is sufficiently conductive (for example, if layer 1016 comprises a graphite anode), current collector layer 1020 is not required.

While the present invention is described in connection with one of the embodiments, it will be understood that it is not intended to limit the invention to this embodiment. On the contrary, it is intended to cover all alternatives, modifications and equivalents as covered by the appended claims.

While the invention has been described with respect to a limited number of embodiments, these should not be construed as limitations on the scope of the invention, but rather as exemplifications of some of the preferred embodiments. Other possible variations, modifications, and applications are also within the scope of the invention. Accordingly, the scope of the invention should not be limited by what has thus far been described, but by the appended claims and their legal equivalents. The principles of the present invention may similarly be applied to other types of electrical storage cells, such as energy-storage capacitors.

The invention has been described in detail with particular reference to certain preferred embodiments thereof, but it will be understood that variations and modifications can be effected within the scope of the invention.

### PARTS LIST

104 digital front end (DFE)
108 imaging device
112 interface line
120 development processor
200 imaging system
204 rotating cylinder
208 imaged film mask with honeycomb shape image
212 imaged data on film (honeycomb shape image)
216 screw
220 imaging head
228 controller
232 carriage
304 honeycomb image
308 walls of the holes (unmasked areas)
312 holes (masked areas)
504 photopolymer plate
508 substrate for imaging
604 perforated holes showing holes diameter from top view
704 distance between perforated holes
708 perforated holes diameter
804 perforated holes pattern showing holes depth from side view
808 side view of perforated holes depth
812 side view of perforated holes diameter
816 perforated holes
904 plate after imaging and development
908 non-solidified areas
912 water jets
1000 perforated substrate
1004 first current collector
1008 cathode layer
1012 electrolyte layer
1016 anode layer
1020 second current collector

1. A method for fabricating an electrical storage cell comprising:
providing a photopolymer substrate;
providing a pre-patterned mask wherein the pre-patterned mask comprises masked regions and unmasked regions;
attaching the pre-patterned mask on top of the photopolymer;
applying collimated ultraviolet radiation on the masked substrate wherein areas of the photopolymer underneath the unmasked regions are solidified or cross linked and areas of the photopolymer underneath the masked are not solidified or cross linked;
developing the imaged substrate;
cleaning residual material from the areas which are not solidified or cross linked to form perforated holes;
forming a thin film over the surface of substrate to define an anode;
forming a solid electrolyte on the anode; and
forming a thin film on the perforated holes to form a cathode.

2. The method according to claim 1 wherein the photopolymer comprises a binder, a monomer, and a photo initiator.

3. The method according to claim 2 wherein the binder is a thermoplastic elastomeric block copolymer.

4. The method according to claim 3 wherein the thermoplastic elastomeric block copolymer may be made of a styrene butadiene styrene, a natural rubber or a styrene-isoprene.

5. The method according to claim 2 wherein the photopolymer comprises acrylate such as isobornyl acrylate, 2-phenoxyethyl acrylate, or a hexane diol diacrylate.

6. The method according to claim 2 wherein the photo initiator is ultra violet (UV) light triggered to start the photopolymer reaction and wherein the photo initiator may be made of a benzophenone or a benzoin.

7. The method according to claim 1 wherein the pre patterned mask is formed by laser imaging.

8. The method according to claim 1 wherein the cleaning of the perforated holes is performed by water jets, brushes, ultra sonic means or a combination thereof.
